(19) United States
(12) Patent Application Publication
(10) Pub. No.: US 2024/0356510 A1
(43) Pub. Date: Oct. 24, 2024

(54) CURRENT SENSOR WITH INPUT COMMON MODE VOLTAGE REDUCTION OR RE-REGISTRATION

(71) Applicant: QUALCOMM Incorporated, San Diego, CA (US)

(72) Inventors: Edward Robert DEAK, Youngsville, NC (US); Yoon Hwee LEOW, Singapore (SG)

(21) Appl. No.: 18/303,476

(22) Filed: Apr. 19, 2023

(51) Int. Cl. H03F 3/45; H03F 3/00

(52) U.S. Cl. CPC H03F 3/45937; H03F 3/005; H03F 3/45475

(57) ABSTRACT

An apparatus, including: a resistive device; a first capacitor selectively coupled in parallel with the resistive device; a second capacitor selectively coupled in parallel with the resistive device; and a common mode voltage source selectively coupled to respective first terminals of the first and second capacitors.

### FIELD

Aspects of the present disclosure relate generally to current sensing, and in particular, to a current sensor configured to sense (e.g., high side) current with a common mode voltage reduction or re-registration.

### BACKGROUND

Many devices/circuits require monitoring a load current they draw from a voltage source, such as a battery, battery charger, voltage regulator, or power management integrated circuit (PMIC). In such scenarios, current sensors are used to sense the load current, and generate a current signal indicative of the load current. Additionally, in such scenarios, current management circuits may be employed to receive current signals from current sensors, and control the currents drawn by devices/circuits for many different reasons, such as power efficiency, thermal control, overcurrent protection, and others.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to an apparatus. The apparatus includes: a resistive device; a first capacitor selectively coupled in parallel with the resistive device; a second capacitor selectively coupled in parallel with the resistive device; and a common mode voltage source selectively coupled to respective first terminals of the first and second capacitors.

Another aspect of the disclosure relates to a method. The method includes generating a first voltage including a first common mode voltage across a resistive device; transferring the first voltage including the first common mode voltage across first and second capacitors during a first phase of operation; and re-referencing the first voltage across the first and second capacitors with a second common mode voltage during a second phase of operation.

Another aspect of the disclosure relates to an apparatus. The apparatus includes means for generating a first voltage including a first common mode voltage across a resistive device; means for transferring the first voltage including the first common mode voltage across first and second capacitors during a first phase of operation; and means for re-referencing the first voltage across the first and second capacitors with a second common mode voltage during a second phase of operation.

Another aspect of the disclosure relates to a wireless communication device. The wireless communication device includes: at least one antenna; a transceiver coupled to the at least one antenna; an integrated circuit (IC) including one or more signal processing cores coupled to the transceiver; a battery coupled to the one or more signal processing cores; and a current sensor coupled to the battery, wherein the current sensor comprises: a resistive device; a first capacitor selectively coupled in parallel with the resistive device; a second capacitor selectively coupled in parallel with the resistive device; and a common mode voltage source selectively coupled to respective first terminals of the first and second capacitors.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 illustrates a block diagram of an example current sensor in accordance with an aspect of the disclosure.

FIG. 2A illustrates a block diagram of another example current sensor in accordance with another aspect of the disclosure.

FIG. 2B illustrates a graph of various signals of the current sensor of FIG. 2A in accordance with another aspect of the disclosure.

FIG. 3 illustrates a block diagram of another example current sensor in accordance with another aspect of the disclosure.

FIG. 4 illustrates a block diagram of another example current sensor in accordance with another aspect of the disclosure.

FIG. 5 illustrates a block diagram of another example current sensor in accordance with another aspect of the disclosure.

FIG. 6 illustrates a flow diagram of an example method of sensing a current in accordance with another aspect of the disclosure.

FIG. 7 illustrates a block diagram of an example wireless communication device in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

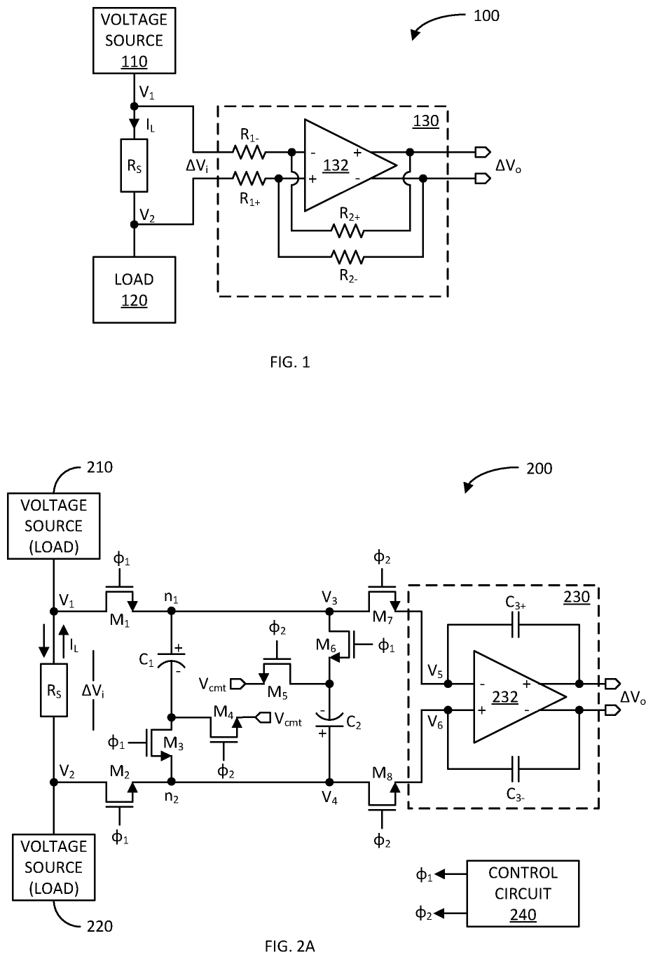

FIG. 1 illustrates a block diagram of an example current sensor 100 in accordance with an aspect of the disclosure. The current sensor 100 may be used for high-side current sensing, where the current sensing is done before a load. However, it shall be understood that the current sensor 100 may also be used in low-side current sensing, where the current sensing is done after the load.

The current sensor 100 includes a voltage source 110, a current sensing resistive device R_{S}, and a load 120, all coupled in series with each other. The voltage source 110 may be any type of voltage source, such as a battery, a battery charger, a voltage regulator, a power management integrated circuit (PMIC), or other. The current sensing resistive device R_{S} may be a resistor (e.g., thin- or thick-film resistor, discrete resistor, etc.) or a semiconductor device (e.g., a field effect transistor (FET)). The load 120 may be one or more cores of a system on chip (SOC), an integrated circuit (IC), a discrete circuit, passive and/or active loads, or other. The voltage source 110 supplies a load current I_{L} to the load 120 via the current sensing resistive device R_{S}.

The current sensor 100 further includes a negative feedback current sense amplifier 130 including input resistors R₁₋ and R₁₊, feedback resistors R₂₊ and R₂₋, and differential operational amplifier 132. The input resistor R₁₋ is coupled between a first terminal of the current sensing resistive device R_{S} (e.g., a node between the voltage source 110 and the current sensing resistive device R_{S}) and a negative input (−) of the operational amplifier 132. The input resistor R₁₊ is coupled between a second terminal of the current sensing resistive device R_{S} (e.g., a node between the current sensing resistive device R_{S} and the load 120) and a positive input (+) of the operational amplifier 132. The feedback resistor R₂₊ is coupled between a positive output (+) and the negative input (−) of the operational amplifier 132. The feedback resistor R₂₋ is coupled between a negative output (−) and the positive input (+) of the operational amplifier 132.

In operation, the voltage source 110 generates a supply voltage (e.g., V₁) to produce a load current I_{L} flowing to the load 120 via the current sensing resistive device R_{S}. The load current I_{L} flowing through the current sensing resistive device R_{S} produces a voltage ΔVᵢ=V₁−V₂ across the resistive device R_{S}, where the voltage V₁ is at the first terminal of the current sensing resistive device R_{S} and voltage V₂ is at the second terminal of the current resistive device R_{S}. Accordingly, the voltage ΔVᵢ across the current sensing resistive device R_{S} is a measure or a function of the load current I_{L} in accordance with Ohm's law (e.g., ΔVᵢ=V₁−V₂=I_{L}*R_{S}, where R_{S} also represents the resistance of the current sensing resistive device R_{S}).

Via the input resistors R₁₋ and R₁₊, the voltage ΔVᵢ across the current sensing resistive device R_{S} is provided to the differential inputs of the negative feedback current sense amplifier 130. The negative feedback current sense amplifier 130 amplifies the voltage ΔVᵢ with a gain G of −R₂/R₁ to generate an output voltage ΔVₒ related to the load current I_{L} (e.g., ΔVₒ=G*ΔVᵢ=G*I_{L}*R_{S}). An analog-to-digital converter (ADC) may be coupled to the output of the negative feedback current sense amplifier 130 to convert the output voltage ΔVₒ into a digital signal for load current I_{L} monitoring and management purposes.

A drawback of the current sensor 100 is that the voltages V₁ and V₂ or common mode voltage V_{cmi} (e.g., V_{cmi}=(V₁+V₂)/2) associated with the voltage ΔVᵢ across the current sensing resistive device R_{S} may be too high for the devices or FETs of the operational amplifier 132. For example, the operational amplifier 132 may have devices that are rated for a maximum gate-to-source voltage (Vgs) of five (5) Volts (V). However, if the voltage source 110 includes two or three stacked battery cells, where each cell generates 5V, the common mode voltage V_{cmi} may be around 10-15V. Thus, the operational amplifier 132 may not be appropriate in such case, where the high voltages (e.g., 10-15V) are beyond the maximum safety voltage levels for the operational amplifier 132.

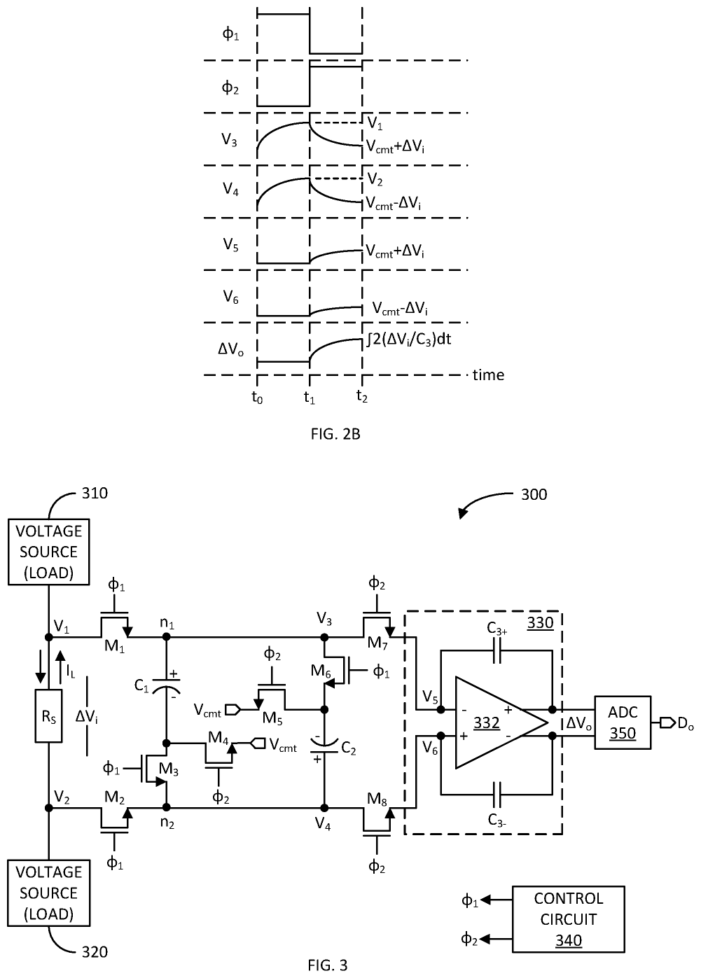

FIG. 2A illustrates a block diagram of another example current sensor 200 in accordance with another aspect of the disclosure. As discussed in more detail further herein, the current sensor 200 is configured to sample the voltage ΔVᵢ including its common mode voltage V_{cmi} across the current sensing resistive device R_{S}, amplify the voltage ΔVᵢ while reducing or re-referencing its common mode voltage, and apply the amplified voltage including the reduced or re-reference common mode voltage to an integrating amplifier. The integrating amplifier generates a voltage, which may be digitized to generate a digital current signal indicative of the load current I_{L}.

In particular, the current sensor 200 includes a first voltage source (or a load) 210, a current sensing resistive device R_{S}, and a second voltage source (or a load) 220, all coupled in series. In some cases, the first voltage source 210 generates a voltage V₁ greater than a voltage V₂ generated by the second voltage source 220 operating as a load in such case, where a load current I_{L} flows from the first voltage source 210 to the second voltage source 220. In other cases, the second voltage source 220 generates a voltage V₂ greater than a voltage V₁ at the first voltage source 210 operating as a load in such case, where a load current I_{L} flows from the second voltage source 220 to the first voltage source 210. Thus, the current sensor 200 may sense bi-directional load current I_{L}. Similarly, the first or second voltage sources (or loads) 210 and 220 may be implemented as a battery, a battery charger, a voltage regulator, a PMIC, one or more cores of an SOC, an IC, a discrete circuit, passive and/or active loads, or other. The current sensing resistive device R_{S} may be a resistor (e.g., thin- or thick-film resistor, discrete resistor, etc.) or a semiconductor device (e.g., FET).

The current sensor 200 further includes a set of switching devices M₁ to M₈, a first capacitor C₁, a second capacitor C₂, and an integrating amplifier 230. Each of the switching devices M₁ to M₈ may be implemented as an n-channel metal oxide semiconductor field effect transistor (NMOS FET). The first and second capacitors C₁ and C₂ may each be implemented as a polarized capacitor including a positive terminal (+) and a negative terminal (−). The integrating amplifier 230, in turn, includes a differential operational amplifier 232 and a pair of feedback capacitors C₃₊ and C₃₋ coupled between positive (+) and negative (−) outputs and negative (−) and positive (+) inputs of the operational amplifier 232, respectively.

The first and seventh switching devices M₁ and M₇ are coupled in series between a first terminal of the current sensing resistive device R_{S} and the negative input (−) of the operational amplifier 232 of the integrating amplifier 230. That is, the first switching device M₁ includes a drain coupled to the first terminal of the current sensing resistive device R_{S}, a gate configured to receive a first control signal ϕ₁, and a source coupled to a first intermediate node n₁. The seventh switching device M₇ includes a drain coupled to the first intermediate node n₁, a gate configured to receive a second control signal ϕ₂, and a source coupled to the negative input (−) of the operational amplifier 232.

Similarly, the second and eighth switching devices M₂ and M₈ are coupled in series between a second terminal of the current sensing resistive device R_{S} and the positive input (+) of the operational amplifier 232 of the integrating amplifier 230. That is, the second switching device M₂ includes a drain coupled to the second terminal of the current sensing resistive device R_{S}, a gate configured to receive the first control signal ϕ₁, and a source coupled to a second intermediate node n₂. The eighth switching device M₈ includes a drain coupled to the second intermediate node n₂, a gate configured to receive the second control signal ϕ₂, and a source coupled to the positive input (+) of the operational amplifier 232.

The first capacitor C₁ and third switching device M₃ are coupled in series between the first and second intermediate nodes n₁ and n₂. That is, the first capacitor C₁ includes a positive terminal (+) coupled to the first intermediate node n₁, and a negative terminal coupled to a drain/source of the third switching device M₃. The third switching device M₃ includes a gate configured to receive the first control signal ϕ₁, and a source/drain coupled to the second intermediate node n₂. The drain/source and source/drain of the third switching device M₃ may be drain and source when the load current I_{L} flows from the first voltage source 210 to the second voltage source 220, or source and drain when the load current I_{L} flows from the second voltage source 220 to the first voltage source 210. Additionally, the fourth switching device M₄ is coupled between the drain/source of the third switching device M₃ and a source of a target common mode voltage V_{cmt}. That is, the fourth switching device M₄ includes a drain coupled to the drain/source of the third switching device M₃, a gate configured to receive the second control signal ϕ₂, and a source coupled to the source of the target common mode voltage V_{cmt}.

Similarly, the sixth switching device M₆ and the second capacitor C₂ are coupled in series between the first and second intermediate nodes n₁ and n₂. That is, the sixth switching device M₆ includes a drain/source coupled to the first intermediate node n₁, a gate configured to receive the first control signal ϕ₁, and a source/drain coupled to a negative terminal (−) of the second capacitor C₂. The drain/source and source/drain of the sixth switching device M₆ may be drain and source when the load current I_{L} flows from the first voltage source 210 to the second voltage source 220, or source and drain when the load current I_{L} flows from the second voltage source 220 to the first voltage source 210. The second capacitor C₂ includes a positive terminal (+) coupled to the second intermediate node n₂. Additionally, the fifth switching device M₅ is coupled between the source/drain of the sixth switching device M₆ and the source of the target common mode voltage V_{cmt}. That is, the fifth switching device M₅ includes a drain coupled to the source/drain of the sixth switching device M₆, a gate configured to receive the second control signal ϕ₂, and a source coupled to the source of the target common mode voltage V_{cmt}.

The current sensor 200 includes a control circuit 240 configured to generate the first and second control signals ϕ₁ and ϕ₂. In operation, in accordance with a first phase of operation, the control circuit 240 asserts (e.g., sets to a logic high) the first control signal ϕ₁ and deasserts (e.g., sets to a logic low) the second control signal ϕ₂. The asserted first control signal ϕ₁ turns on switching devices M₁, M₂, M₃, and M₆, and the deasserted second control signal ϕ₂ turns off switching devices M₄, M₅, M₇, and M₈. The turned-on switching devices M₁, M₂, M₃, and M₆ cause the voltage ΔVᵢ across the current sensing resistive device R_{S} to be transferred across the first and second capacitors C₁ and C₂. The turned-off switching devices M₇ and M₈ isolate the input common mode voltage V_{cmi} (e.g., V_{cmi}=(V₁+V₂)/2) from the differential inputs of the operational amplifier 232. For example, the input common mode voltage V_{cmi} may be relatively high (e.g., 10-15V), which, if they were to be applied to the differential inputs of the operational amplifier 232, may exceed the voltage rating of the devices (e.g., FETs) of the operational amplifier 232. The turned-off switching devices M₄ and M₅ isolate the source of the target common mode voltage V_{cmt} from the first and second capacitors C₁ and C₂, respectively.

In accordance with a second phase of operation, the control circuit 240 deasserts (e.g., sets to a logic low) the first control signal ϕ1 and asserts (e.g., sets to a logic high) the second control signal ϕ₂. The deasserted first control signal ϕ1 turns off switching devices M₁, M₂, M₃, and M₆, and the asserted second control signal ϕ₂ turns on switching devices M₄, M₅, M₇, and M₈. As switching devices M₇ and M₈ are turned on during the second phase, the turned-off switching devices M₁ and M₂ isolate the differential inputs of the operational amplifier 232 from the high input common mode voltage V_{cmi} at the first and second terminals of the current sensing resistive device R_{S}. The turned-on switching devices M₄ and M₅ apply the target common mode voltage V_{cmt} to the negative terminals of the first and second capacitors C₁ and C₂ (the turned-off switching devices M₃ and M₆ isolate the second and first intermediate nodes n₂ and n₁ from the negative terminals of the first and second capacitors C₁ and C₂, respectively). The turned-on switching devices M₁ and M₈ route the current sense voltage ΔVᵢ with the reduced or re-referenced common mode voltage V_{cmt} to the differential inputs of the operational amplifier 232, where the current sense voltage ΔVᵢ with the reduced or re-referenced common mode voltage V_{cmt} do not exceed the voltage rating of the devices of the operational amplifier 232.

As an example, the devices or FETs of the operational amplifier 232 may have a maximum voltage rating of 5V. The voltage ΔVᵢ across the current sensing resistive device R_{S} may be 100 milliVolts (mV), with an input common mode voltage V_{cmi} of around 15V (e.g., V₁=15, V₂=14.9, and V_{cmi}=14.95V). If the target common mode voltage V_{cmt} is set to 2.5V, then voltage ΔVᵢ of 100 mV with the target common mode voltage V_{cmt} of 2.5V (e.g., V₅=2.6V, V₆=2.4V, and V_{cmt}=2.5V) is applied to the differential inputs of the operational amplifier 232. Thus, the reduced or re-referenced common mode voltage V_{cmt} (e.g., 2.5V) is within the maximum voltage rating (e.g., 5V) of the devices or FETs of the operational amplifier 232.

FIG. 2B illustrates a graph of various signals of the current sensor 200 in accordance with another aspect of the disclosure. The x- or horizontal-axis represents time from t₀ to t₂.

The vertical axis, from top to bottom, represents the state or voltage levels of the first control signal ϕ₁, the second control signal ϕ₂, the voltage V₃ at the first intermediate node n₁, the voltage V₄ at the second intermediate node n₂, the voltage V₅ at the negative input (−) of the operational amplifier 232, the voltage V₆ at the positive input (+) of the operational amplifier 232, and the output voltage ΔVₒ of the integrating amplifier 230.

The first phase of operation is between time t₀ and t₁. During the first phase, the first control signal ϕ₁ is asserted, and the second control signal ϕ₂ is deasserted. As a result of the first phase of operation, the voltage V₃ rises to substantially V₁ and the voltage V₄ rises substantially to V₂. Accordingly, the first and second capacitors C₁ and C₂ are charged to ΔVᵢ=V₁−V₂ with a common mode voltage V_{cmi}=(V₁+V₂)/2. During the first phase, the voltages V₅ and V₆ at the differential inputs of the integrating amplifier 230 may be substantially 0V; and thus, the output voltage ΔVₒ of the integrating amplifier 230 may also be substantially 0V.

The second phase of operation is between time t₁ and t₂. During the second phase, the first control signal ϕ₁ is deasserted, and the second control signal ϕ₂ is asserted. As a result of the second phase of operation, the voltage V₃ decreases to substantially V_{cmt}+ΔVᵢ and the voltage V₄ decreases to substantially V_{cmt}-ΔVᵢ. Thus, the common mode voltage associated with the current sensing voltage ΔVᵢ has been reduced or re-referenced to a level safe to provide to the operational amplifier 232. As the switching devices M₇ and M₈ are turned on during the second phase, the voltages V₅ and V₆ rise substantially to V_{cmt}+ΔVᵢ and V_{cmt}−ΔVᵢ, respectively. Accordingly, the differential voltage at the input of the integrating amplifier 230 is V₅−V₆=(V_{cmt}+ΔVᵢ)−(V_{cmt}−ΔVᵢ)=2ΔVᵢ. This also results in a six (6) decibels (dB) increase in the signal-to-noise ratio (SNR) associated with sensing the load current I_{L}, as the differential voltage 2ΔVᵢ at the inputs of the integrating amplifier 230 is twice the differential voltage ΔVᵢ across the current sensing resistive device R_{S}. The integrating amplifier 230 integrates the differential voltage 2ΔVᵢ to generate an output voltage ΔVₒ. Accordingly, in this configuration, the output voltage ΔVₒ may be related to the product of the differential or input voltage 2ΔVᵢ to the operational amplifier 232 and the ratio of the capacitance of either the first or second capacitor C₁ or C₂ and the capacitance of either feedback capacitor C₃₊ or C₃₋, respectively.

FIG. 3 illustrates a block diagram of another example current sensor 300 in accordance with another aspect of the disclosure. The current sensor 300 may be a variation or an augmentation of the current sensor 200 previously discussed, and includes many of the same/similar elements as indicated by the same reference numbers with the exception that the most significant digit is a “3” for current sensor 300 where it is a “2” for current sensor 200. In addition to the same/similar components of the current sensor 200, the current sensor 300 includes an analog-to-digital converter (ADC) 350 including differential inputs coupled to the differential outputs of the integrating amplifier 330 to receive the output voltage ΔVₒ therefrom. The ADC 350 is configured to convert the output voltage ΔVₒ into a digital signal Do for current monitoring and management by a power/current management circuit, such as one residing in or associated with an SOC.

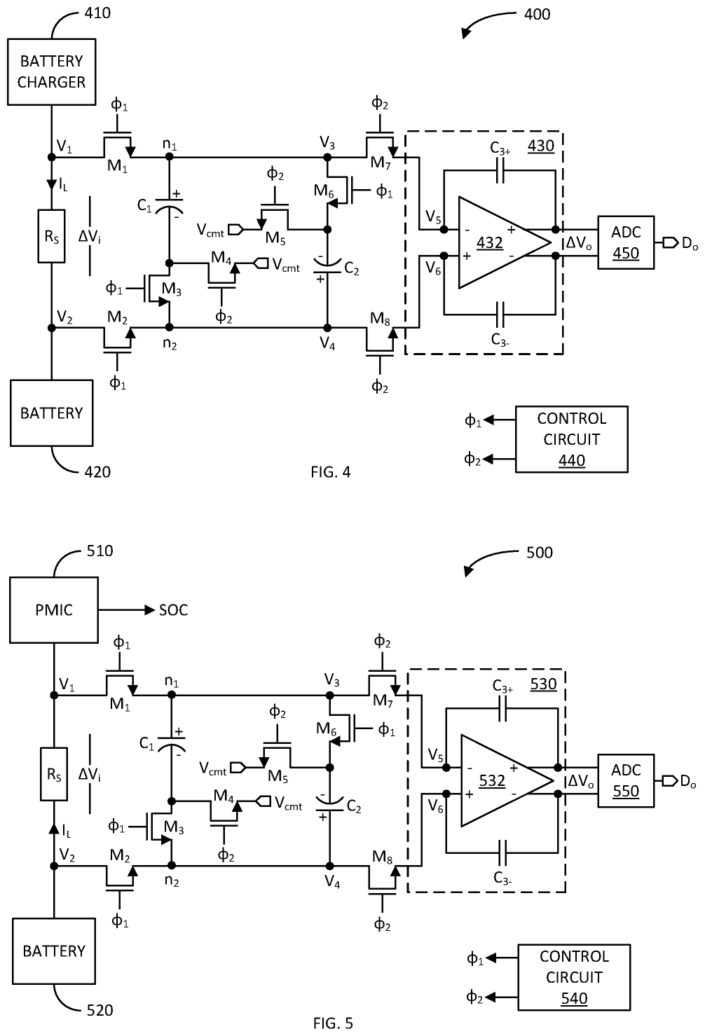

FIG. 4 illustrates a block diagram of another example current sensor 400 in accordance with another aspect of the disclosure. The current sensor 400 may be a specific use case or configuration of the current sensor 300 previously discussed, and includes many of the same/similar elements as indicated by the same reference numbers with the exception that the most significant digit is a “4” for current sensor 400 where it is a “3” for current sensor 300. In accordance with the use case or configuration of current sensor 400, the first voltage source 410 is a battery charger, and the second voltage source 420 is a battery 420. Accordingly, when the battery charger 410 is charging the battery 420, the load current I_{L} is flowing from the battery charger 410 to the battery 420 via the current sensing resistive device R_{S}. Accordingly, as previously discussed in detail, the current sensor 400 generates a digital signal D_{O} indicative of the battery charging current I_{L}.

FIG. 5 illustrates a block diagram of another example current sensor 500 in accordance with another aspect of the disclosure. The current sensor 500 may be another specific use case or configuration of the current sensor 300 previously discussed, and includes many of the same/similar elements as indicated by the same reference numbers with the exception that the most significant digit is a “5” for current sensor 500 where it is a “3” for current sensor 300. In accordance with the use case or configuration of current sensor 500, the first voltage source 510 is a power management integrated circuit (PMIC), and the second voltage source 520 is a battery 520. Accordingly, the PMIC 510 receives the voltage V₁ from the battery 520 to generate one or more regulated voltages for an SOC or other circuitry or load. In this use case or configuration, the load current I_{L} is flowing from the battery 520 to the PMIC 510 via the current sensing resistive device R_{S}. Accordingly, as previously discussed in detail, the current sensor 500 generates a digital signal D_{O} indicative of the current I_{L} supplied by the battery 520 to the PMIC 510.

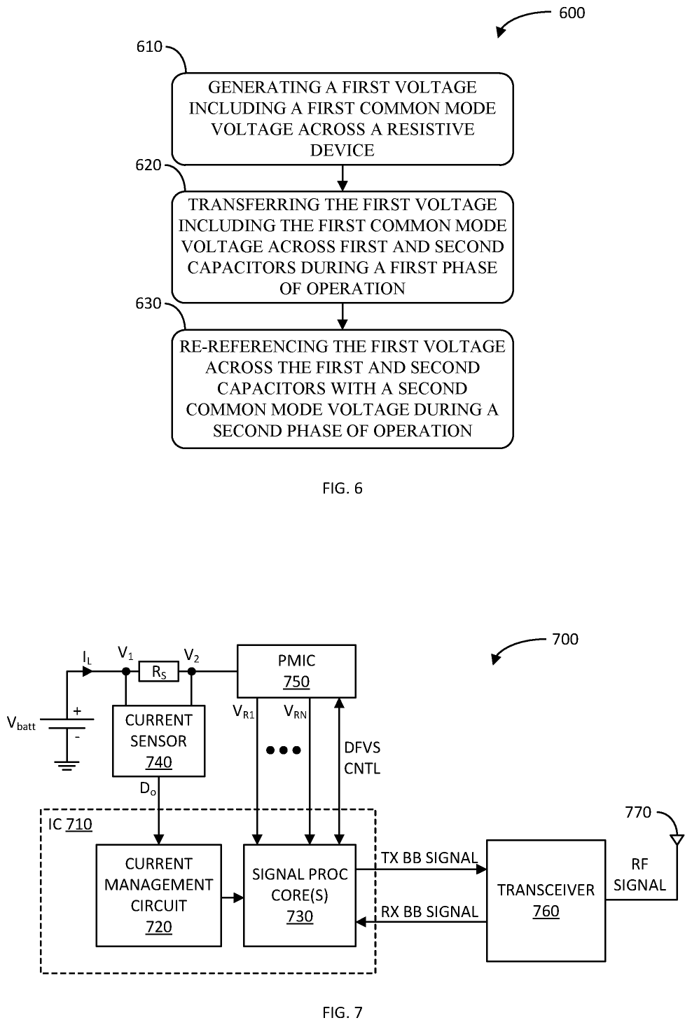

FIG. 6 illustrates a flow diagram of an example method 600 of sensing a current in accordance with another aspect of the disclosure. The method 600 includes generating a first voltage including a first common mode voltage across a resistive device (block 610). Examples of means for generating a first voltage including a first common mode voltage across a resistive device include any of the current sensing resistive devices described herein.

The method 600 further includes transferring the first voltage including the first common mode voltage across first and second capacitors during a first phase of operation (block 620). Examples of means for transferring the first voltage including the first common mode voltage across first and second capacitors during a first phase of operation include the switching devices M₁, M₂, M₃, and M₆, and the control circuits for controlling the aforementioned switching devices.

Further, the method 600 includes re-referencing the first voltage across the first and second capacitors with a second common mode voltage during a second phase of operation (block 630). Examples of means for re-referencing the first voltage across the first and second capacitors with a second common mode voltage during a second phase of operation include the switching devices M₄ and M₅, the control circuits for controlling the aforementioned switching devices, and the source of the target common mode voltage V_{cmt}.

FIG. 7 illustrates a block diagram of an example wireless communication device 700 in accordance with another aspect of the disclosure. The wireless communication device 700 may be a smart phone, a desktop computer, laptop computer, tablet device, Internet of Things (IoT), wearable wireless device (e.g., wireless watch), and other types of wireless device.

In particular, the wireless communication device 700 includes an integrated circuit (IC) 710, which may be implemented as a system on chip (SOC). The IC 710 includes one or more signal processing cores 730 configured to generate a transmit (Tx) baseband (BB) signal and process a received (Rx) baseband (BB) signal.

The IC 710 further includes a current management circuit 720 for controlling the operations of the one or more signal processing cores 730 based on a digital current signal D_{O} generated by a current sensor 740. The current sensor 740, which may be implemented per any of the current sensors 200, 300, 400, and 500 previously discussed, generates the digital current signal D_{O} based on a load current I_{L} supplied by a battery V_{batt} to a power management integrated circuit (PMIC) 750 by sensing a voltage ΔV=V₁−V₂ across a current sensing resistive device R_{S}, as previously discussed.

The PMIC 750 uses the voltage V₂ to generate a set of one or more regulated voltages V_{R1} to V_{RN} for the one or more signal processing cores 730. The one or more signal processing cores 730 may further be coupled to the PMIC 750 via a dynamic frequency voltage scaling (DFVS) control link for setting the one or more regulated voltages V_{R1} to V_{RN} based on certain operation modes of the one or more signal processing cores 730, which, as discussed, may be controlled by the current management circuit 720 based on the digital current signal D_{O}.

The wireless communication device 700 may further include a transceiver 760 and at least one antenna 770 (e.g., an antenna array). The transceiver 760 is coupled to the one or more signal processing cores 730 to receive therefrom the Tx BB signal and provide thereto the Rx BB signal. The transceiver 760 is configured to convert the Tx BB signal into a transmit (Tx) radio frequency (RF) signal, and convert a received (Rx) RF signal into the Rx BB signal. The transceiver 760 is coupled to the at least one antenna 770 to provide thereto the Tx RF signal for electromagnetic radiation into a wireless medium for wireless transmission, and receive the Rx RF signal electromagnetically picked up from the wireless medium by the at least one antenna 770.

The following provides an overview of aspects of the present disclosure:

Aspect 1: An apparatus, comprising: a resistive device; a first capacitor selectively coupled in parallel with the resistive device; a second capacitor selectively coupled in parallel with the resistive device; and a common mode voltage source selectively coupled to respective first terminals of the first and second capacitors.

Aspect 2: The apparatus of aspect 1, further comprising a control circuit configured to: couple the resistive device in parallel with the first and second capacitors during a first phase of operation; decouple the resistive device from the first and second capacitors during a second phase of operation; and couple the common mode voltage source to the first terminals of the first and second capacitors during the second phase of operation.

Aspect 3: The apparatus of aspect 2, further comprising: a first switching device coupled between a first terminal of the resistive device and a second terminal of the first capacitor; a second switching device coupled between a second terminal of the resistive device and a second terminal of the second capacitor; a third switching device coupled between the first terminal of the first capacitor and the second terminal of the second capacitor; and a fourth switching device coupled between the first terminal of the second capacitor and the second terminal of the first capacitor; wherein the control circuit is configured to turn on the first, second, third, and fourth switching devices to couple the resistive device in parallel with the first and second capacitors during the first phase of operation.

Aspect 4: The apparatus of aspect 3, wherein the first and second capacitors are polarized capacitors, wherein the first terminals of the first and second capacitors are negative terminals of the polarized capacitors, and wherein the second terminals of the first and second capacitors are positive terminals of the polarized capacitors.

Aspect 5: The apparatus of aspect 3 or 4, wherein at least one of the first, second, third, and fourth switching devices comprises a field effect transistor (FET).

Aspect 6: The apparatus of any one of aspects 3-5, further comprising: a fifth switching device coupled between the first terminal of the first capacitor and the common mode voltage source; and a sixth switching device coupled between the first terminal of the second capacitor and the common mode voltage source; wherein the control circuit is configured to turn on the fifth and sixth switching devices to couple the common mode voltage source to the first terminals of the first and second capacitors during the second phase of operation.

Aspect 7: The apparatus of aspect 6, wherein at least one of the fifth and sixth switching devices comprises a field effect transistor (FET).

Aspect 8: The apparatus of aspect 6 or 7, further comprising: a differential amplifier including first and second differential inputs; a seventh switching device coupled between the first switching device and the first differential input of the differential amplifier; and an eighth switching device coupled between the second switching device and the second differential input of the differential amplifier; wherein the control circuit is configured to turn on the seventh and eighth switching devices to couple the second terminals of the first and second capacitors to the first and second differential inputs during the second phase of operation, respectively.

Aspect 9: The apparatus of aspect 8, wherein at least one of the seventh and eighth switching devices comprises a field effect transistor (FET).

Aspect 10: The apparatus of aspect 8 or 9, wherein the differential amplifier comprises an integrating differential amplifier.

Aspect 11: The apparatus of any one of aspects 8-10, wherein the differential amplifier comprises: an operational amplifier including the first and second differential inputs and first and second differential outputs; a third capacitor coupled between the first differential input and the first differential output; and a fourth capacitor coupled between the second differential input and the second differential output.

Aspect 12: The apparatus of any one of aspects 8-11, further comprising an analog-to-digital converter (ADC) coupled to the differential amplifier.

Aspect 13: The apparatus of aspect 11 or 12, wherein the third and fourth capacitors are in a connection relationship with the first and second capacitors such that an output voltage of the operational amplifier is related to a product of twice an input voltage of the operational amplifier and a ratio of a capacitance of the first or second capacitor to a capacitance of the third or fourth capacitor.

Aspect 14: The apparatus of any one of aspects 1-13, further comprising: a first voltage source coupled to a first terminal of the resistive device; and a second voltage source coupled to a second terminal of the resistive device.

Aspect 15: The apparatus of aspect 14, wherein the first voltage source comprises a battery charger, and the second voltage source comprises a battery.

Aspect 16: The apparatus of aspect 14, wherein the first voltage source comprises a power management integrated circuit (PMIC), and the second voltage source comprises a battery.

Aspect 17: The apparatus of any one of aspects 1-13, further comprising: a voltage source coupled to a first terminal of the resistive device; and a load coupled to a second terminal of the resistive device.

Aspect 18: The apparatus of any one of aspects 1-17, wherein the resistive device comprises a resistor.

Aspect 19: The apparatus of any one of aspects 1-18, wherein the resistive device comprises a field effect transistor (FET).

Aspect 20: A method, comprising: generating a first voltage including a first common mode voltage across a resistive device; transferring the first voltage including the first common mode voltage across first and second capacitors during a first phase of operation; and re-referencing the first voltage across the first and second capacitors with a second common mode voltage during a second phase of operation.

Aspect 21: The method of aspect 20, wherein re-referencing the first voltage across the first and second capacitors with the second common mode voltage comprises applying the second common mode voltage to terminals of the first and second capacitors, respectively.

Aspect 22: The method of aspect 21, wherein the first and second capacitors are polarized capacitors, and the terminals of the first and second capacitors are negative terminals of the polarized capacitors.

Aspect 23: The method of any one of aspects 20-22, further comprising isolating the first and second capacitors from the resistive device during the second phase of operation.

Aspect 24: The method of any one of aspects 20-23, further comprising generating a second voltage across differential inputs of a differential amplifier based on the first voltage including the second common mode voltage during the second mode of operation, wherein the second voltage is different than the first voltage.

Aspect 25: An apparatus, comprising: means for generating a first voltage including a first common mode voltage across a resistive device; means for transferring the first voltage including the first common mode voltage across first and second capacitors during a first phase of operation; and means for re-referencing the first voltage across the first and second capacitors with a second common mode voltage during a second phase of operation.

Aspect 26: The apparatus of aspect 25, wherein the means for re-referencing the first voltage across the first and second capacitors with the second common mode voltage comprises means for applying the second common mode voltage to terminals of the first and second capacitors, respectively.

Aspect 27: The apparatus of aspect 26, wherein the first and second capacitors are polarized capacitors, and the terminals of the first and second capacitors are negative terminals of the polarized capacitors.

Aspect 28: The apparatus of any one of aspects 25-27, further comprising means for isolating the first and second capacitors from the resistive device during the second phase of operation.

Aspect 29: A wireless communication device, comprising: at least one antenna; a transceiver coupled to the at least one antenna; an integrated circuit (IC) including one or more signal processing cores coupled to the transceiver; a battery coupled to the one or more signal processing cores; and a current sensor coupled to the battery, wherein the current sensor comprises: a resistive device; a first capacitor selectively coupled in parallel with the resistive device; a second capacitor selectively coupled in parallel with the resistive device; and a common mode voltage source selectively coupled to respective first terminals of the first and second capacitors.

Aspect 30: The wireless communication device of aspect 29, wherein the current sensor further comprises a control circuit configured to: couple the resistive device in parallel with the first and second capacitors during a first phase of operation; decouple the resistive device from the first and second capacitors during a second phase of operation; and couple the common mode voltage source to the first terminals of the first and second capacitors during the second phase of operation.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. An apparatus, comprising:
a resistive device;
a first capacitor selectively coupled in parallel with the resistive device;
a second capacitor selectively coupled in parallel with the resistive device; and
a common mode voltage source selectively coupled to respective first terminals of the first and second capacitors.

2. The apparatus of claim 1, further comprising a control circuit configured to:
couple the resistive device in parallel with the first and second capacitors during a first phase of operation;
decouple the resistive device from the first and second capacitors during a second phase of operation; and
couple the common mode voltage source to the first terminals of the first and second capacitors during the second phase of operation.

3. The apparatus of claim 2, further comprising:
a first switching device coupled between a first terminal of the resistive device and a second terminal of the first capacitor;
a second switching device coupled between a second terminal of the resistive device and a second terminal of the second capacitor;
a third switching device coupled between the first terminal of the first capacitor and the second terminal of the second capacitor; and
a fourth switching device coupled between the first terminal of the second capacitor and the second terminal of the first capacitor;
wherein the control circuit is configured to turn on the first, second, third, and fourth switching devices to couple the resistive device in parallel with the first and second capacitors during the first phase of operation.

4. The apparatus of claim 3, wherein the first and second capacitors are polarized capacitors, wherein the first terminals of the first and second capacitors are negative terminals of the polarized capacitors, and wherein the second terminals of the first and second capacitors are positive terminals of the polarized capacitors.

5. The apparatus of claim 3, wherein at least one of the first, second, third, and fourth switching devices comprises a field effect transistor (FET).

6. The apparatus of claim 3, further comprising:
a fifth switching device coupled between the first terminal of the first capacitor and the common mode voltage source; and
a sixth switching device coupled between the first terminal of the second capacitor and the common mode voltage source;
wherein the control circuit is configured to turn on the fifth and sixth switching devices to couple the common mode voltage source to the first terminals of the first and second capacitors during the second phase of operation.

7. The apparatus of claim 6, wherein at least one of the fifth and sixth switching devices comprises a field effect transistor (FET).

8. The apparatus of claim 6, further comprising:
a differential amplifier including first and second differential inputs;
a seventh switching device coupled between the first switching device and the first differential input of the differential amplifier; and
an eighth switching device coupled between the second switching device and the second differential input of the differential amplifier;
wherein the control circuit is configured to turn on the seventh and eighth switching devices to couple the second terminals of the first and second capacitors to the first and second differential inputs during the second phase of operation, respectively.

9. The apparatus of claim 8, wherein at least one of the seventh and eighth switching devices comprises a field effect transistor (FET).

10. The apparatus of claim 8, wherein the differential amplifier comprises an integrating differential amplifier.

11. The apparatus of claim 8, wherein the differential amplifier comprises:
an operational amplifier including the first and second differential inputs and first and second differential outputs;
a third capacitor coupled between the first differential input and the first differential output; and
a fourth capacitor coupled between the second differential input and the second differential output.

12. The apparatus of claim 11, further comprising an analog-to-digital converter (ADC) coupled to the differential amplifier.

13. The apparatus of claim 11, wherein the third and fourth capacitors are in a connection relationship with the first and second capacitors such that an output voltage of the operational amplifier is related to a product of twice an input voltage of the operational amplifier and a ratio of a capacitance of the first or second capacitor to a capacitance of the third or fourth capacitor.

14. The apparatus of claim 1, further comprising:
a first voltage source coupled to a first terminal of the resistive device; and
a second voltage source coupled to a second terminal of the resistive device.

15. The apparatus of claim 14, wherein the first voltage source comprises a battery charger, and the second voltage source comprises a battery.

16. The apparatus of claim 14, wherein the first voltage source comprises a power management integrated circuit (PMIC), and the second voltage source comprises a battery.

17. The apparatus of claim 1, further comprising:
a voltage source coupled to a first terminal of the resistive device; and
a load coupled to a second terminal of the resistive device.

18. The apparatus of claim 1, wherein the resistive device comprises a resistor.

19. The apparatus of claim 1, wherein the resistive device comprises a field effect transistor (FET).

20. A method, comprising:
generating a first voltage including a first common mode voltage across a resistive device;
transferring the first voltage including the first common mode voltage across first and second capacitors during a first phase of operation; and
re-referencing the first voltage across the first and second capacitors with a second common mode voltage during a second phase of operation.

21. The method of claim 20, wherein re-referencing the first voltage across the first and second capacitors with the second common mode voltage comprises applying the second common mode voltage to terminals of the first and second capacitors, respectively.

22. The method of claim 21, wherein the first and second capacitors are polarized capacitors, and the terminals of the first and second capacitors are negative terminals of the polarized capacitors.

23. The method of claim 20, further comprising isolating the first and second capacitors from the resistive device during the second phase of operation.

24. The method of claim 20, further comprising generating a second voltage across differential inputs of a differential amplifier based on the first voltage including the second common mode voltage during the second mode of operation, wherein the second voltage is different than the first voltage.

25. An apparatus, comprising:
means for generating a first voltage including a first common mode voltage across a resistive device;
means for transferring the first voltage including the first common mode voltage across first and second capacitors during a first phase of operation; and
means for re-referencing the first voltage across the first and second capacitors with a second common mode voltage during a second phase of operation.

26. The apparatus of claim 25, wherein the means for re-referencing the first voltage across the first and second capacitors with the second common mode voltage comprises means for applying the second common mode voltage to terminals of the first and second capacitors, respectively.

27. The apparatus of claim 26, wherein the first and second capacitors are polarized capacitors, and the terminals of the first and second capacitors are negative terminals of the polarized capacitors.

28. The apparatus of claim 25, further comprising means for isolating the first and second capacitors from the resistive device during the second phase of operation.

29. A wireless communication device, comprising:
at least one antenna;
a transceiver coupled to the at least one antenna;
an integrated circuit (IC) including one or more signal processing cores coupled to the transceiver;
a battery coupled to the one or more signal processing cores; and
a current sensor coupled to the battery, wherein the current sensor comprises:
a resistive device;
a first capacitor selectively coupled in parallel with the resistive device;
a second capacitor selectively coupled in parallel with the resistive device; and
a common mode voltage source selectively coupled to respective first terminals of the first and second capacitors.

30. The wireless communication device of claim 29, wherein the current sensor further comprises a control circuit configured to:
couple the resistive device in parallel with the first and second capacitors during a first phase of operation;
decouple the resistive device from the first and second capacitors during a second phase of operation; and
couple the common mode voltage source to the first terminals of the first and second capacitors during the second phase of operation.
